(19) United States
(12) Patent Application Publication
(10) Pub. No.: US 2025/0280564 A1
(43) Pub. Date: Sep. 4, 2025

(54) THIN-FILM TRANSISTOR AND DISPLAY APPARATUS INCLUDING THE SAME

(71) Applicant: LG Display Co., Ltd., Seoul (KR)

(72) Inventor: Sungju CHOI, Paju-si (KR)

(73) Assignee: LG Display Co., Ltd., Seoul (KR)

(21) Appl. No.: 19/049,482

(22) Filed: Feb. 10, 2025

(30) Foreign Application Priority Data
Feb. 29, 2024 (KR) 10-2024-0030014

(51) Int. Cl. H10D 30/67; H10K 59/121; H10K 59/124

(52) U.S. Cl. CPC H10D 30/6706; H10D 30/6757; H10K 59/1213; H10K 59/124

(57) ABSTRACT

A display apparatus including a light-emitting element and a thin-film transistor electrically connected to the light-emitting element is disclosed. In an embodiment, the thin-film transistor includes a substrate, an active layer disposed on the substrate, a gate electrode disposed on the active layer, a buffer layer disposed between the active layer and the substrate. The-film transistor includes a semiconductor structure disposed under at least a portion of the buffer layer and overlapping at least a portion of the active layer from a plan view.

### CROSS-REFERENCE TO RELATED APPLICATION

This application claims priority from Korean Patent Application No. 10-2024-0030014 filed on Feb. 29, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a thin-film transistor and a display apparatus including the thin-film transistor.

### Description of the Related Art

Display apparatus are applied to various electronic devices such as TVs (Televisions), smartphones, laptops, and tablets. To this end, research is being conducted to develop smaller, lighter, and lower power consuming display apparatuses.

Examples of the display apparatus include a liquid crystal display apparatus (LCD), a field emission display apparatus (FED), and an organic light emitting display apparatus (OLED).

A transistor is used as an element that controls each of a plurality of pixels included in the display apparatus. The display apparatus may include at least one thin-film transistor.

### BRIEF SUMMARY

Various embodiments of the present disclosure provide a thin-film transistor capable of achieving a high S factor without reducing a driving current, and a display apparatus including the same.

Various embodiments of the present disclosure provide a thin-film transistor including different areas having capacitances of different magnitudes in one thin-film transistor, and a display apparatus including the same.

Various embodiments of the present disclosure provide a thin-film transistor capable of advantageously performing grayscale expression and a display apparatus including the same.

Technical benefits of the present disclosure are not limited to the above-mentioned benefits and other advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

The thin-film transistor according to an embodiment of the present disclosure may include: a substrate; an active layer disposed on the substrate; a gate electrode disposed on the active layer; a buffer layer disposed between the active layer and the substrate; and a semiconductor structure disposed under at least a portion of the buffer layer and overlapping at least a portion of the active layer from a plan view.

A display apparatus according to an embodiment of the present disclosure may include a light-emitting element; and a thin-film transistor connected to the light-emitting element, wherein the thin-film transistor may include: a substrate; an active layer disposed on the substrate; a gate electrode disposed on the active layer; a buffer layer disposed between the active layer and the substrate; and a semiconductor structure disposed under at least a portion of the buffer layer and overlapping at least a portion of the active layer when seen from a plan view.

According to an embodiment of the present disclosure, the thin-film transistor may have capacitances having different magnitudes in different areas arranged in the width direction of the channel area, such that the S-factor value may be increased without reducing the total driving current Ion.

Accordingly, the high S-factor value required for the low-grayscale expression may be secured without reducing the driving current. Thus, the thin-film transistor may advantageously perform various grayscale expressions.

Furthermore, according to an embodiment of the present disclosure, the buffer layer may be formed to have the structure to have capacitances of different magnitudes in a single thin-film transistor. Thus, the thin-film transistor may not be subjected to the trade-off between the S factor and the driving current, which may be applied to the conventional thin-film transistor in which the buffer layer is formed as a single flat layer.

Accordingly, the reliability of the thin-film transistor may be increased, and the production energy saving effect may be realized through process optimization.

In addition, the semiconductor structure may be disposed so as to face the active layer, that is, overlap therewith, and thus may absorb the ultraviolet rays in an amount corresponding to a band gap of a semiconductor material of the semiconductor structure, such that the reliability of the active layer may be improved.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a schematic diagram of a display apparatus according to an embodiment of the present disclosure.

FIG. 2 is a diagram showing a circuit of a pixel area in a display apparatus according to an embodiment of the present disclosure.

FIG. 3 is a plan view of a thin-film transistor according to an embodiment of the present disclosure.

FIG. 4 is a cross-sectional view taken along a line I-I′ of FIG. 3.

FIGS. 5A to 5E are cross-sectional views illustrating a method for manufacturing a thin-film transistor according to an embodiment of the present disclosure.

FIG. 6 shows a variant example of a thin-film transistor according to an embodiment of the present disclosure.

FIG. 7 shows a variant example of a thin-film transistor according to an embodiment of the present disclosure.

FIG. 8 shows a variant example of a thin-film transistor according to an embodiment of the present disclosure.

FIG. 9 is a plan view of a thin-film transistor according to another embodiment of the present disclosure.

FIG. 10 is a cross-sectional view taken along a line II-II′ of FIG. 9.

FIG. 11 shows a variant example of a thin-film transistor according to another embodiment of the present disclosure.

FIG. 12 shows a variant example of a thin-film transistor according to another embodiment of the present disclosure.

FIG. 13 shows a variant example of a thin-film transistor according to another embodiment of the present disclosure.

FIG. 14 is a graph of a current-voltage curve of a thin-film transistor.

FIG. 15A is a diagram showing a structure for controlling a capacitance ratio of a thin-film transistor.

FIG. 15B is a graph showing a trade-off relationship between a S-factor and a driving current of a thin-film transistor.

FIG. 16 is a cross-sectional view showing one of pixel areas of a display apparatus including a thin-film transistor according to an embodiment of the present disclosure in an enlarged manner.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc., disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, a display apparatus according to each of embodiments of the present disclosure is described with reference to the attached drawings.

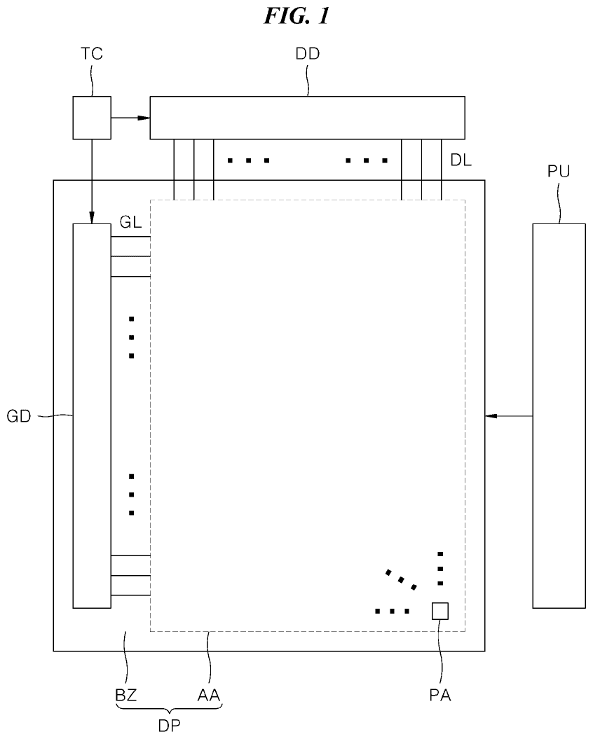

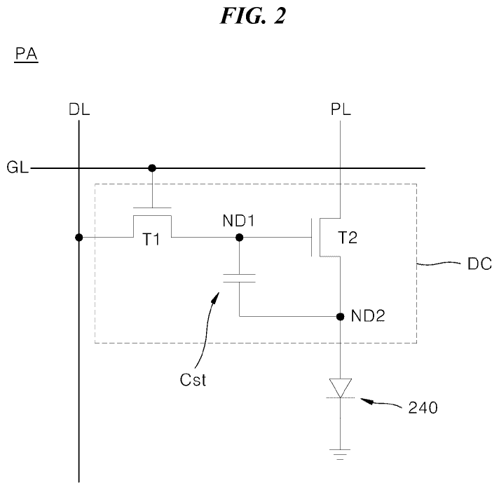

FIG. 1 is a schematic diagram of a display apparatus according to an embodiment of the present disclosure. FIG. 2 is a diagram showing a circuit of a pixel area in a display apparatus according to an embodiment of the present disclosure.

Referring to FIGS. 1 and 2, the display apparatus according to an embodiment of the present disclosure may include a display panel DP. The display panel DP may generate an image or video provided to a user. For example, a plurality of pixel areas PA may be disposed in the display panel DP. Various signals may be transmitted to each of the pixel areas PA via signal lines GL, DL, and PL. For example, the signal lines GL, DL, and PL may include gate lines GL, data lines DL, and power voltage supply lines PL.

The gate lines GL may sequentially apply a gate signal to each pixel area PA. The data lines DL may apply a data signal to each pixel area PA. The power voltage supply lines PL may supply a power voltage to each pixel area PA. The gate lines GL may be electrically connected to a gate driver GD. The data lines DL may be electrically connected to a data driver DD.

The gate driver GD and the data driver DD may be controlled by a timing controller TC. For example, the gate driver GD may receive clock signals, reset signals, and a start signal from the timing controller TC, and the data driver DD may receive digital video data and a source timing signal from the timing controller TC. The power supply voltage lines PL may be electrically connected to a power unit PU.

The display panel DP may include an active area AA where pixel areas PA are disposed and a bezel area BZ disposed outside the active area AA. The bezel area BZ may be disposed outside the pixel areas PA. For example, the active area AA may be surrounded with the bezel area BZ. At least one of the gate driver GD, the data driver DD, the timing controller TC, and the power unit PU may be disposed on the bezel area BZ of the display panel DP. For example, the display apparatus according to an embodiment of the present disclosure may be a GIP (Gate In Panel) type display apparatus in which the gate driver GD is formed on the bezel area BZ of the display panel DP. Each of the signal lines GL, DL, and PL may include a portion disposed on the bezel area BZ. The active area AA may be referred to as a display area, and the bezel area BZ may be referred to as a non-display area.

Each pixel area PA may emit light of a specific color. For example, the pixel areas PA may be implemented to emit light of different colors, such as red (R), green (G), and blue (B) colors. Alternatively, the pixel areas PA may be implemented to emit light of the same color, such as white (W) light.

A light-emitting element 240 and a pixel driving circuit DC electrically connected to the light-emitting element 240 may be disposed within each pixel area PA.

The signal lines GL, DL, and PL may be electrically connected to the pixel driving circuit DC of each pixel area PA. For example, the pixel driving circuit DC of each pixel area PA may be electrically connected to one of the gate lines GL, one of the data lines DL, and one of the power voltage supply lines PL. The pixel driving circuit DC of each pixel area PA may supply a driving current corresponding to a data signal to the light-emitting element 240 of the pixel area PA for one frame in response to the gate signal.

The pixel driving circuit DC of each pixel area PA may include a first thin-film transistor T1, a second thin-film transistor T2, and a storage capacitor Cst.

The first thin-film transistor T1 may be, for example, a switching transistor. The first thin-film transistor T1 may apply a voltage of the data line DL to a first node ND1. The first thin-film transistor T1 may be turned on or off based on a scan signal. The first node ND1 may be connected to a gate electrode of the second thin-film transistor T2.

The second thin-film transistor T2 may be, for example, a driving thin-film transistor. The second thin-film transistor T2 may operate so that a driving current flows based on the data voltage stored in the storage capacitor Cst. The second thin-film transistor T2 may be turned on based on the data voltage to control the current flowing through the light-emitting element 240 so that an image or video may be displayed. A first node ND2 may be connected to the light-emitting element 240. The light-emitting element 240 may emit light under the current transmitted through the second thin-film transistor T2.

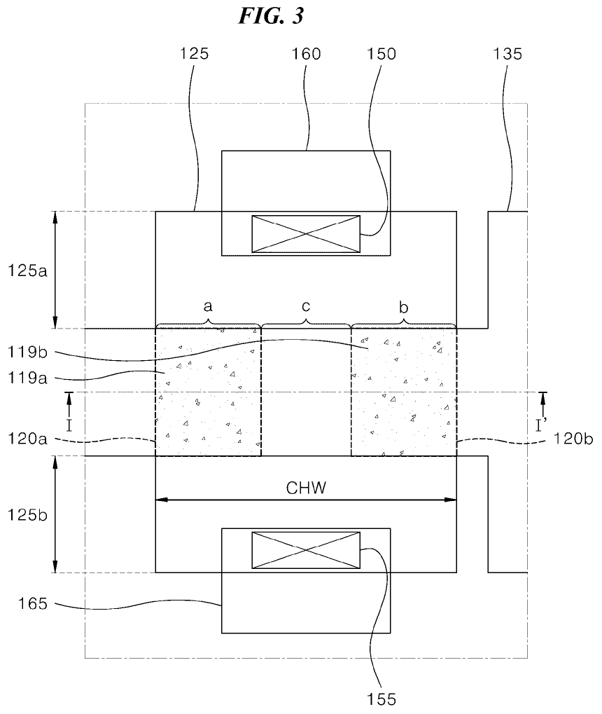

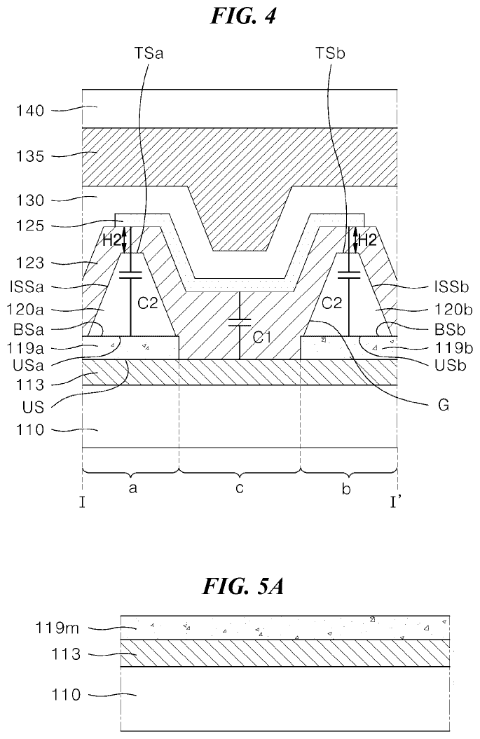

Hereinafter, a thin-film transistor according to an embodiment of the present disclosure will be described with reference to FIG. 3 and FIG. 4. The thin-film transistor as described in the present disclosure may be a driving thin-film transistor as at least the second thin-film transistor T2 among the first thin-film transistor T1 and the second thin-film transistor T2. However, embodiments of the present disclosure are not limited thereto.

FIG. 3 is a plan view of a thin-film transistor according to one embodiment of the present disclosure. FIG. 4 is a cross-sectional view taken along a line I-I′ of FIG. 3.

Referring to FIG. 3 and FIG. 4, an active layer 125 may be disposed on a substrate 110, and a gate electrode 135 may be disposed on the active layer 125. A buffer layer 123 may be disposed between the active layer 125 and the substrate 110. A semiconductor structure 119a and 119b overlapping at least a portion of the active layer 125 may be included under the buffer layer 123.

A light-blocking layer 113 may be disposed on the substrate 110. The substrate 110 may include glass or plastic. The plastic substrate may include polyimide. However, embodiments of the present disclosure are not limited thereto.

The thin-film transistor as described in the present disclosure may be a driving thin-film transistor. However, embodiments of the present disclosure are not limited thereto. The driving thin-film transistor may be turned on based on the voltage to control the current flowing though the light-emitting element to display an image.

The light-blocking layer 113 may be disposed to overlap the active layer 125 in a vertical direction. For example, the light-blocking layer 113 may have at least the same area size as that of the active layer 125 or a larger area size than that of the active layer 125.

The light-blocking layer 113 may block light incident thereto from an outside. The active layer 125 of the thin-film transistor 100 may be protected by the light-blocking layer 113. To this end, the light-blocking layer 113 may include a material that is electrically conductive and may block light incident thereto from the outside. For example, the light-blocking layer 113 may be formed as a single layer or a stack of multiple layers made of one or more opaque metal materials selected from the group of molybdenum (Mo), aluminum (Al), titanium (Ti), or copper (Cu), or an alloy thereof. However, the present disclosure is not limited thereto. The light-blocking layer 113 may include a low-reflection metal material.

The semiconductor structure 119a and 119b may be disposed on the light-blocking layer 113. The semiconductor structure 119a and 119b may include one or more semiconductor patterns. For example, the semiconductor structure 119a and 119b may include a first semiconductor pattern 119a and a second semiconductor pattern 119b. The first semiconductor pattern 119a and the second semiconductor pattern 119b may be positioned to be in contact with an upper surface US of the light-blocking layer 113.

The first semiconductor pattern 119a and the second semiconductor pattern 119b may be arranged to be spaced apart from each other by a spacing. Each of the first semiconductor pattern 119a and the second semiconductor pattern 119b may include a silicon-based semiconductor material.

Each of the first semiconductor pattern 119a and the second semiconductor pattern 119b may include amorphous silicon containing first conductive impurities. For example, the first conductive impurity may include a p-type impurity. The p-type impurity may include boron (B), indium (In), gallium (Ga), or aluminum (Al). In another example, each of the first semiconductor pattern 119a and the second semiconductor pattern 119b may include a semiconductor material into which the first conductive impurity may be doped.

Each of the first semiconductor pattern 119a and the second semiconductor pattern 119b may have one surface in contact with the light-blocking layer 113. The first semiconductor pattern 119a and the second semiconductor pattern 119b may further prevent external light from being incident on the active layer 125.

The light-blocking layer 113 may be disposed on the substrate 110 so as to prevent the light from the outside out of the substrate 110 from being incident on the active layer 125. However, while the thin-film transistor is operating, the active layer 125 may be exposed to light. Alternatively, the active layer 125 may be exposed to light, particularly, ultraviolet light due to diffuse reflection, etc.

An oxide semiconductor constituting the active layer 125 has instability such as NBIS (negative bias illumination stress) which undesirably increases current when being exposed to light.

Each of the first semiconductor pattern 119a and the second semiconductor pattern 119b may absorb ultraviolet rays in an amount corresponding to a band gap of the semiconductor material. Accordingly, in an embodiment of the present disclosure, the light incident on the active layer 125 may be absorbed by the first semiconductor pattern 119a and the second semiconductor pattern 119b together with the light-blocking layer 113, thereby preventing the reliability of the active layer 125 from being deteriorated.

Spacer patterns 120a and 120b may be disposed on upper surfaces USa, USb of the first semiconductor pattern 119a and the second semiconductor pattern 119b, respectively. The spacer patterns 120a and 120b may include the first spacer pattern 120a and the second spacer pattern 120b. The first spacer pattern 120a may be disposed on the first semiconductor pattern 119a, and the second spacer pattern 120b may be disposed on the second semiconductor pattern 119b.

The first spacer pattern 120a and the second spacer pattern 120b are disposed on the upper surfaces of the first semiconductor pattern 119a and the second semiconductor pattern 119b, respectively, such that a space G that exposes a portion of the light-blocking layer 113 may be defined.

A width of each of the first and second spacer patterns 120a and 120b may become smaller as each of the first and second spacer patterns 120a and 120b extends upwardly. Accordingly, the width of a bottom surface BSa, BSb of each of the first and second spacer patterns 120a and 120b may be larger than the width of a upper surface TSa, TSb thereof. In this case, each of the first and second spacer patterns 120a and 120b may include an inclined side surface ISSa, ISSb extending from the upper surface to the bottom surface thereof.

Each of the first spacer pattern 120a and the second spacer pattern 120b may have a thickness that is larger than a thickness of each of the first semiconductor pattern 119a and the second semiconductor pattern 119b. For example, each of the first spacer pattern 120a and the second spacer pattern 120b may have the thickness that is at least twice as large as the thickness of each of the first semiconductor pattern 119a and the second semiconductor pattern 119b. However, embodiments of the present disclosure are not limited thereto.

Each of the first spacer pattern 120a and the second spacer pattern 120b may include silicon oxide (SiOₓ) or silicon nitride (SiNₓ). However, embodiments of the present disclosure are not limited thereto. For example, each of the first spacer pattern 120a and the second spacer pattern 120b may be formed as a multilayer in which one or more insulating films are alternately stacked on top of each other.

The buffer layer 123 may be disposed on the substrate 110. The buffer layer 123 may be positioned to cover an exposed surface of each of the first spacer pattern 120a, the second spacer pattern 120b, and the light-blocking layer 113. The buffer layer 123 may cover the inclined side surface of each of the first spacer pattern 120a and the second spacer pattern 120b.

The buffer layer 123 may include silicon oxide (SiOₓ) or silicon nitride (SiNₓ). However, embodiments of the present disclosure are not limited thereto. For example, the buffer layer 123 may be formed as a multilayer in which one or more insulating films are alternately stacked on top of each other.

The buffer layer 123 may reduce or prevent penetration of moisture, oxygen, or impurities through the substrate 110 into the thin-film transistor 100 to protect the thin-film transistor 100.

The buffer layer 123 may fill the space G between the first spacer pattern 120a and the second spacer pattern 120b. The buffer layer 123 may be formed in the space G so as to have a first thickness H1. The buffer layer 123 may cover the upper surface of each of the first spacer pattern 120a and the second spacer pattern 120b so as to have a second thickness H2.

A vertical level of an upper surface of a portion of the buffer layer 123 disposed on the upper surface of each of the first spacer pattern 120a and the second spacer pattern 120b may be higher than a vertical level of an upper surface of a portion of the buffer layer 123 disposed in the space G between the first spacer pattern 120a and the second spacer pattern 120b. Accordingly, the buffer layer 123 may have a concave-convex upper surface.

The active layer 125 may be disposed on the buffer layer 123. The active layer 125 may include an oxide semiconductor material. For example, the active layer 125 may include an oxide semiconductor material such as indium-gallium-zinc-oxide (IGZO) or indium-zinc-oxide (IZO), but is not limited to such materials.

The active layer 125 may extend along the concave-convex upper surface of the buffer layer 123 in a conformal manner. Accordingly, the active layer 125 may have a concave-convex structure. For example, the active layer 125 may include a first portion disposed on top of the first spacer pattern 120a, a second portion disposed on top of the second spacer pattern 120b, and a third portion extending between the first portion and the second portion and having a relatively lower vertical level than a vertical level of each of the first portion and the second portion. The active layer 125 may include a ‘U’ shape in a cross-sectional view.

A gate insulating layer 130 may be disposed on the active layer 125. The gate insulating layer 130 may include a single layer or a stack of multiple layers made of silicon oxide (SiOₓ) or silicon nitride (SiNₓ). However, embodiments of the present disclosure are not limited thereto. The gate insulating layer 130 may extend along the concave-convex upper surface of the active layer 125 in a conformal manner.

A gate electrode 135 may be disposed on the gate insulating layer 130. The gate electrode 135 may be positioned to overlap with the active layer 125 in the vertical direction.

Referring to FIG. 3, the gate electrode 135 may have a relatively smaller width in a direction perpendicular to the CHW (channel area width) direction than that of the active layer 125. A portion of the active layer 125 that overlaps with the gate electrode 135 in the vertical direction may act as a channel area. A first portion 125a of the active layer 125 that does not overlap with the gate electrode 135 may act as a source area, and a second portion 125b of the active layer 125 that does not overlap with the gate electrode 135 may act as a drain area. However, the present disclosure is not limited thereto. For example, the first portion 125a may act as a drain area, and the second portion 125b may act as a source area.

The first semiconductor pattern 119a and the second semiconductor pattern 119b may be positioned to be spaced apart from each other in a width CHW direction of the channel area with the buffer layer 123 therebetween.

In this case, in a plan view, in the width CHW direction of the channel area, a portion of the channel area where the first semiconductor pattern 119a is disposed may be a first area a, a portion of the channel area where the second semiconductor pattern 119b is disposed may be a second area b, and a portion of the channel area where the first semiconductor pattern 119a and the second semiconductor pattern 119b are not disposed but the space G is disposed may be a third area c.

In the first area a of the channel area, one side area in the width CHW direction of the channel area of the active layer 125 may overlap the gate electrode 135. In the second area b of the channel area, the other side area in the width CHW direction of the channel area of the active layer 125 may overlap the gate electrode 135. The third area c may be disposed between the first area a and the second area b.

An interlayer insulating layer 140 may be disposed on the gate electrode 135. The interlayer insulating layer 140 may include a single layer or a stack of multiple layers made of silicon oxide (SiOₓ) or silicon nitride (SiNₓ). However, the present disclosure is not limited thereto.

A first electrode 160 and a second electrode 165 may be disposed on the interlayer insulating layer 140. The first electrode 160 may be connected to the first area 125a as one side area in a direction perpendicular to the CHW direction of the active layer 125 via a first contact hole 150 extending through the interlayer insulating layer 140 and the gate insulating layer 130. Furthermore, the second electrode 165 may be connected to the second area 125b as the other side area in the direction perpendicular to the CHW direction of the active layer 125 via a second contact hole 155 extending through the interlayer insulating layer 140 and the gate insulating layer 130.

The thin-film transistor may comprise the active layer 125, the gate electrode 135, the first electrode 160, and the second electrode 165 formed in the above described manner.

According to an embodiment of the present disclosure, in the third area c of the thin-film transistor, the portion of the buffer layer 123 of the first thickness H1 (which may be also called as a first part of the buffer layer 123) may be disposed between the light-blocking layer 113 and the active layer 125 such that a first capacitance C1 may be generated.

In the first area a, the first spacer pattern 120a and a portion of the buffer layer 123 of the second thickness H2 (which may be also called as a second part of the buffer layer 123) are disposed between the active layer 125 and the first semiconductor pattern 119a so that a second capacitance C2 may be generated. In addition, in the second area b, the second spacer pattern 120b and a portion of the buffer layer 123 having the second thickness H2 (which may be also called as a third part of the buffer layer 123) may be disposed between the active layer 125 and the second semiconductor pattern 119b, so that the same second capacitance C2 as that generated in the first area a may be generated.

In this case, the first thickness HI of the portion of the buffer layer 123 disposed in the space G between the first semiconductor pattern 119a and the second semiconductor pattern 119b may be larger than the second thickness H2.

In the first area a including the first spacer pattern 120a and the buffer layer 123, the second capacitance C2 may be generated between the first semiconductor pattern 119a and the light-blocking layer 113 and the active layer 125. In the first area b including the second spacer pattern 120b and the buffer layer 123, the second capacitance C2 may be generated between the active layer 125 and the second semiconductor pattern 119b and the light-blocking layer 113.

In this regard, in the third area c, a portion of the buffer layer 123 may be disposed between the active layer 125 and the light-blocking layer 113 such that the first capacitance C1 may be generated. Accordingly, in each of the first area a and the second area b in which the second capacitance C2 may be generated, the second thickness H2 of the portion of the buffer layer 123 is relatively smaller than the first thickness H1 of the portion of the buffer layer 123 in the third area c.

Accordingly, the second capacitance C2 of each of the first area a and the second area b may be larger than the first capacitance C1 of the third area c.

The magnitudes of the second capacitances C2 of the first area a and the second area b may be equal to each other.

Furthermore, the second capacitance C2 of the first area and the second capacitance C2 of the second area may be generated symmetrically with each other while being respectively disposed on both opposing sides of the first capacitance C1 of the third area interposed therebetween.

In each of the first area a and the second area b where the second capacitance C2 is generated, a threshold voltage may increase, while in the third area c where the first capacitance C1 is generated, a threshold voltage may decrease relatively compared to that in each of the first area a and the second area b. In the first area a and the second area b, the first and second spacer patterns 120a and 120b and the buffer layer 123 may be disposed, respectively, such that a thickness of each of the first area a and the second area b is larger than a thickness of the third area c. Thus, a driving current Ion in each of the first area a and the second area b may have a first current amount. In addition, since the third area c is free of the spacer pattern but includes only the buffer layer 123 and has a relatively smaller thickness than that of the first area a or the second area b, the driving current Ion in the third area c may have a second current amount greater than the first current amount.

Accordingly, the driving current Ion of the thin-film transistor may have a third current amount as the sum of the first current amounts and the second current amount based on the current characteristic of the transistors connected to each other in a parallel manner in the channel width CHW direction. In an embodiment of the present disclosure, by configuring capacitances C1, C2 of different magnitudes in each area a, b, c in one thin-film transistor, the current amount of the total driving current Ion may be increased.

Therefore, while the driving current Ion may not be lowered, the S-factor may be controlled to have a high value. Thus, while the switching characteristics of the thin-film transistor may be maintained, low-gray level expression may be advantageously achieved.

The S-factor is referred to as “subthreshold slope” and indicates a voltage required when the current increases by 10 times. In a graph (I-V curve) showing characteristics of a drain current relative to a gate voltage. The S-factor value is a reciprocal value of a slope of the graph (I-V curve) in a range below the threshold voltage.

A small S-factor value means that the slope of the characteristic graph I-V of the drain current relative to the gate voltage is large. Therefore, the thin-film transistor may be turned on even under a small voltage, and the switching characteristics of the thin-film transistor may be improved. On the other hand, since the voltage reaches the threshold voltage in a short time, it may be difficult to express sufficient gray levels.

Conversely, a large S-factor value means that the slope of the characteristic graph I-V of the drain current relative to the gate voltage is small. Therefore, the switching characteristics of the thin-film transistor may deteriorate due to decrease in an on/off response speed of the thin-film transistor, while sufficient grayscale expression may be achieved because the voltage reaches the threshold voltage over a relatively long period of time.

The S-factor value may increase or decrease depending on a capacitance ratio C_{BUF}/C_{GI} between a capacitance C_{BUF} between the active layer 125 and the buffer layer 123 and a capacitance C_{GI} between the gate electrode 135 and the active layer 125.

The S-factor value based on the capacitance ratio C_{BUF}/C_{GI} may be determined based on a following [Relationship 1]:

S-factor∝(1+C_{BUF}/C_{GI}) [Relationship 1]

According to the [Relationship 1], the S-factor value may increase as the magnitude of the capacitance C_{BUF} between the active layer 125 and the buffer layer 123 increases.

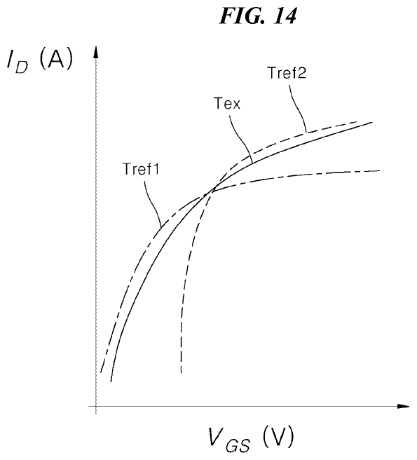

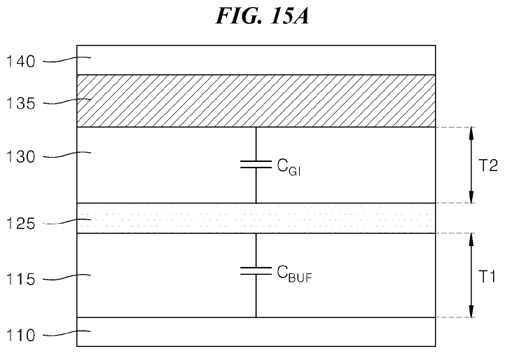

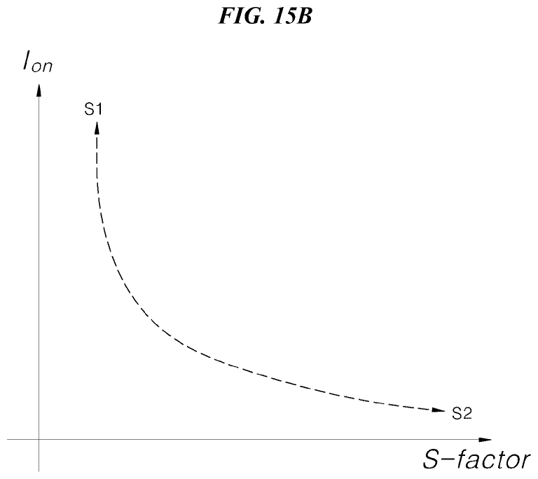

FIG. 14 is a graph of the current-voltage curve of the thin-film transistor. FIG. 15A is a diagram showing a structure for controlling the capacitance ratio of the thin-film transistor. FIG. 15B is a graph showing a trade-off relationship between the S-factor and the driving current of the thin-film transistor.

Referring to FIG. 15A, one of schemes for increasing the magnitude of the capacitance C_{BUF} between the active layer 125 and the buffer layer 115 may include increasing the thickness T1 of the buffer layer 115 to be larger than the thickness T2 of the gate insulating layer 130. In another example, a scheme for increasing the magnitude of the capacitance C_{BUF} between the active layer 125 and the buffer layer 115 may include changing a material of the buffer layer 115 so as to change a dielectric constant thereof.

As the magnitude of the capacitance C_{BUF} between the active layer 125 and the buffer layer 115 increases, the S-factor value may increase, while the driving current Ion magnitude decreases. Thus, the S-factor value and the driving current Ion has a trade-off relationship relative to each other.

The magnitude of the driving current Ion based on the magnitude of the capacitance C_{BUF} between the active layer 125 and the buffer layer 115 may be determined based on a following [Relationship 2]:

Driving current Ion∝(1+C_{BUF}/C_{GI})⁻¹ [Relationship 2]

According to the above [Relationship 2], the driving current Ion may decrease as the magnitude of the capacitance C_{BUF} between the active layer 125 and the buffer layer 115 increases. When the driving current Ion decreases, an operation efficiency of a compensation circuit may decrease. When the operation efficiency of the compensation circuit decreases, a defect such as a panel stain may occur.

Referring to FIG. 15B, it may be identified that the S-factor and the driving current Ion of the thin-film transistor have a trade-off relationship in which the current amount of the driving current Ion increases when the S-factor decreases as indicated by S1, and the current amount of the driving current Ion decreases when the S-factor increases as indicated by S2.

Referring to FIG. 14 together with FIG. 15A, the driving current Ion of Comparative Example 1 Tref1 in which the thickness of the buffer layer 115 is reduced to generate the capacitance may be represented as a first current amount. In addition, the driving current Ion of Comparative Example 2 Tref2 in which the thickness of the buffer layer 115 is increased to generate the capacitance may be represented as a second current amount.

In this regard, according to an embodiment of the present disclosure, in one thin-film transistor, the second capacitance C2 of the first area a and the second capacitance C2 of the second area b may be generated symmetrically with each other while being respectively disposed on both opposing sides of the first capacitance C1 of the third area interposed therebetween. Accordingly, according to the current characteristics of the parallel connected transistors, a third current amount Tex as the sum of the first current amounts and the second current amount may be the driving current Ion of the thin-film transistor according to an embodiment of the present disclosure.

Accordingly, a high S-factor value may be secured without a decrease in the current amount of the driving current Ion, so that the thin-film transistor may achieve sufficient low-gray level expression. While the active layer 125 is made of the oxide semiconductor material in order to apply a high current level to the thin-film transistor, the high S-factor for sufficient low-gray level expression may be secured.

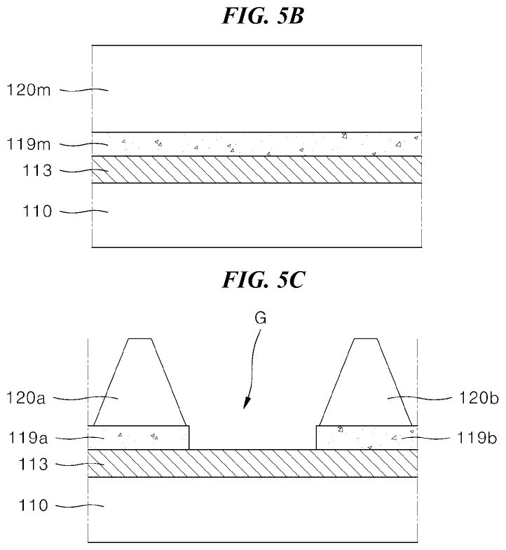

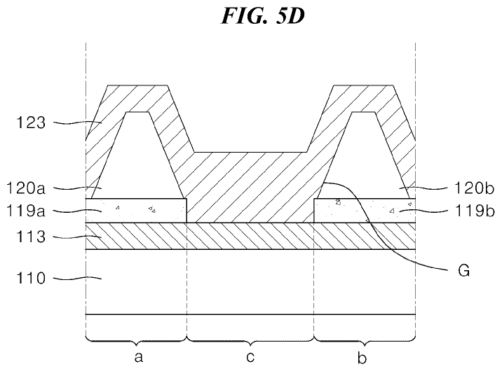

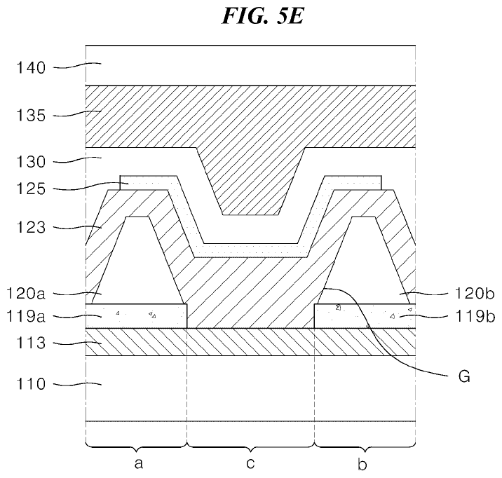

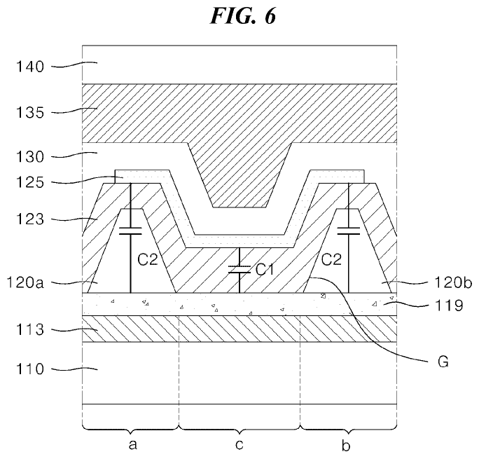

FIGS. 5A to 5E are cross-sectional views illustrating a method for manufacturing a thin-film transistor according to an embodiment of the present disclosure. In FIGS. 5A to 5E, the same reference numerals are assigned to the components having same reference numerals of the thin-film transistors as described above with reference to FIGS. 3 and 4, and the descriptions thereof are simplified or omitted.

Referring to FIG. 5A, the light-blocking layer 113 and a semiconductor base layer 119m are formed on the substrate 110. The light-blocking layer 113 and the semiconductor base layer 119m may be sequentially stacked upwardly on the substrate 110.

The semiconductor base layer 119m may be formed by forming an undoped semiconductor base layer and then performing a doping process of injecting impurities therein. The semiconductor base layer 119m may be doped with a first conductive impurity. The semiconductor base layer 119m may include an amorphous silicon layer. However, embodiments of the present disclosure are not limited thereto. For example, the semiconductor base layer 119m may include a semiconductor material that may be doped with the first conductive impurity. The first conductive impurity may include a p-type impurity. The p-type impurity may include boron (B), indium (In), gallium (Ga), or aluminum (Al).

Referring to FIG. 5B, a spacer base layer 120m is formed on the semiconductor base layer 119m. The spacer base layer 120m may include an insulating material.

Referring to FIG. 5C, an etching process is performed on the spacer base layer 120m and the semiconductor base layer 119m. The etching process may be stopped at a point where a surface of a partial area of the light-blocking layer 113 is exposed. A stack of the spacer base layer 120m and the semiconductor base layer 119m may be divided into stack structures spaced from each other in the etching process.

One stack structure may include the first semiconductor pattern 119a, and the first spacer pattern 120a disposed on the first semiconductor pattern 119a. In addition, the other stack structure may include the second semiconductor pattern 119b, and the second spacer pattern 120b disposed on the second semiconductor pattern 119b. The space G may be defined between the two stack structures.

A portion of the light-blocking layer 113 may be exposed through the space G. For example, one side area around the space G may be the first area a in which the first semiconductor pattern 119a and the first spacer pattern 120a are stacked. The other side area around the space G may be the second area b in which the second semiconductor pattern 119b and the second spacer pattern 120b are stacked. The space G may correspond to the third area c.

Referring to FIG. 5D, the buffer layer 123 is formed on the substrate 110. The buffer layer 123 may fill the space G. In addition, the buffer layer 123 may cover the upper surfaces of the first spacer pattern 120a and the second spacer pattern 120b. Accordingly, the buffer layer 123 may comprise different areas of different thicknesses, that is, the first area a, the second area b, and the third area c. For example, the portion of the buffer layer 123 disposed in the third area c may have a larger thickness than a thickness of the portion of the buffer layer 123 disposed in each of the first area a and the second area b. The buffer layer 123 may have the same thickness in the first area a and the second area b. However, embodiments of the present disclosure are not limited thereto.

A portion of the buffer layer 123 in the third area c where the gap space G is disposed may have the upper surface having the vertical level lower than the vertical level of the upper surface of the portion of the buffer layer 123 in each of the first area a where the first spacer pattern 120a is disposed and the second area b where the second spacer pattern 120b is disposed. Accordingly, the buffer layer 123 may include a concave-convex upper surface including at least one inclined surface.

Referring to FIG. 5E together with FIG. 3, the active layer 125 is formed on the buffer layer 123. The active layer 125 may include an oxide semiconductor material. The active layer 125 may be formed along a profile of the buffer layer 123 including the concave-convex upper surface including the inclined surface in a conformal manner. For example, the active layer 125 may have a ‘U’ shape in a cross-sectional view. However, embodiments of the present disclosure are not limited thereto.

The vertical levels of the upper surfaces in the first area a, the second area b, and the third area c of the active layer 125 may be different from each other. Accordingly, the entire upper surface area size of the active layer 125 may be relatively increased compared to that in a case when the active layer 125 is formed to have a flat upper surface.

The gate insulating layer 130 and the gate electrode 135 may be formed on the active layer 125. The gate electrode 135 may be positioned to overlap with the active layer 125 in the vertical direction. A portion of the active layer 125 overlapping the gate electrode 135 may be the channel area. The first portion 125a of the active layer 125 that does not overlap with the gate electrode 135 may be a source area, and the second portion 125b of the active layer 125 that does not overlap with the gate electrode 135 may be a drain area. The source area and the drain area may be respectively disposed on both opposing sides of the gate electrode 135 while the channel area is disposed therebetween.

The interlayer insulating layer 140 is formed on the gate electrode 135. The interlayer insulating layer 140 may include the first contact hole 150 and the second contact hole 155 that expose the first portion 125a and the second portion 125b, respectively.

The first electrode 160 may be electrically connected to the first portion 125a of the active layer 125 while filling the first contact hole 150. In addition, the second electrode 165 may be electrically connected to the second portion 125b of the active layer 125 while filling the second contact hole 155.

FIG. 6 shows a variant example of a thin-film transistor according to an embodiment of the present disclosure. In FIG. 6, the same components as those of the thin-film transistor as described above with reference to FIG. 4 are given the same reference numerals, and the descriptions thereof are simplified or omitted.

Referring to FIG. 6, a semiconductor layer 119 may be disposed on the substrate 110 on which the light-blocking layer 113 has been disposed.

The semiconductor layer 119 may include a silicon-based semiconductor material. The semiconductor layer 119 may include amorphous silicon doped with a first conductive impurity. For example, the first conductive impurity may include a p-type impurity. The p-type impurity may include boron (B), indium (In), gallium (Ga), or aluminum (Al). In another example, the semiconductor layer 119 may include a semiconductor material that may be doped with the first conductive impurity.

The semiconductor layer 119 may be positioned to contact one surface of the light-blocking layer 113 in the first area a and the second area b, as well as in the third area c, and may be positioned to face the active layer 125. In this case, the third area c may further absorb the ultraviolet rays in an amount corresponding to the band gap of the semiconductor layer 119. Accordingly, in this embodiment of the present disclosure, the light incident on the active layer 125 may be absorbed by the light-blocking layer 113 and the semiconductor layer 119, such that the reliability of the active layer 125 including the oxide semiconductor may be prevented from being deteriorated.

The first spacer pattern 120a and the second spacer pattern 120b may be disposed on the semiconductor layer 119 so as to be disposed on both opposing sides of the space G while the space G may be defined therebetween. A width of each of the first and second spacer patterns 120a and 120b may become smaller as each of the first and second spacer patterns 120a and 120b extends upwardly. Accordingly, the width of a bottom surface of each of the first and second spacer patterns 120a and 120b may be larger than the width of a upper surface thereof. In this case, each of the first and second spacer patterns 120a and 120b may include an inclined side surface extending from the upper surface to the bottom surface thereof.

Each of the first spacer pattern 120a and the second spacer pattern 120b may have a thickness larger than the thickness of the semiconductor layer 119. Each of the first spacer pattern 120a and the second spacer pattern 120b may include silicon oxide (SiOₓ) or silicon nitride (SiNₓ). However, embodiments of the present disclosure are not limited thereto. For example, each of the first spacer pattern 120a and the second spacer pattern 120b may be formed as a multilayer in which one or more insulating films are alternately stacked on top of each other.

The buffer layer 123 may be disposed on the first spacer pattern 120a, the second spacer pattern 120b, and the semiconductor layer 119. The buffer layer 123 may cover the inclined surface and the upper surface of each of the first spacer pattern 120a and the second spacer pattern 120b.

The buffer layer 123 may fill the space G defined between the first spacer pattern 120a and the second spacer pattern 120b. Furthermore, the buffer layer 123 may be disposed on the upper surface of each of the first spacer pattern 120a and the second spacer pattern 120b.

The active layer 125 may be disposed on the buffer layer 123. The active layer 125 may be extend along the prefile of the convex-concave upper surface of the buffer layer 123 in the conformal manner. The active layer 125 may extend to a position corresponding to or overlapping the upper surface of the first spacer pattern 120a and a position corresponding to or overlapping the upper surface of the second spacer pattern 120b. Accordingly, the active layer 125 may have a ‘U’ shape in the cross-sectional view. However, embodiments of the present disclosure are not limited thereto.

The gate insulating layer 130, the gate electrode 135, and the interlayer insulating layer 140 may be disposed on the active layer 125 to constitute the thin-film transistor.

According to an embodiment of the present disclosure, the thin-film transistor may be configured to have the first capacitance C1 in the third area c, and the second capacitance C2 in each of the first area a and the second area b. The magnitude of the second capacitance C2 may be greater than the magnitude of the first capacitance C1. The second capacitances C2 respectively generated in the first area a and the second area b may have the same magnitude. In addition, each of the first area a and the second area b may include a driving current Ion of a first current amount, and the third area c may include a driving current Ion of a second current amount greater than the first current amount.

Accordingly, an entire current amount of the driving current Ion of the thin-film transistor may be a third current amount as a sum of the first current amount and the second current amount.

Therefore, the S-factor value may be controlled to have a high value while the driving current Ion is not lowered. Thus, the switching characteristics of the thin-film transistor may be maintained while the thin-film transistor may advantageously achieve the low-gray level expression.

Furthermore, the semiconductor layer 119 is disposed in the third area c so as to face the active layer 125. Thus, external light incident toward the active layer 125 may be absorbed by the semiconductor layer 119, thereby preventing the reliability of the active layer 125 including the oxide semiconductor from being lowered.

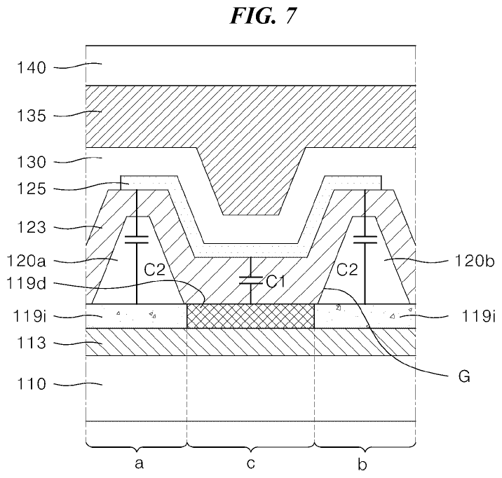

FIG. 7 shows a variant example of a thin-film transistor according to an embodiment of the present disclosure. In FIG. 7, the same components as those of the thin-film transistor as described above with reference to FIG. 4 are given the same reference numerals, and the descriptions thereof are simplified or omitted.

Referring to FIG. 7, a semiconductor structure 119i and 119d may be disposed on the light-blocking layer 113. The semiconductor structure 119i and 119d may include one or more semiconductor patterns.

For example, the semiconductor structure 119i and 119d may include a third semiconductor pattern 119i and a fourth semiconductor pattern 119d. Each of the third semiconductor pattern 119i and the fourth semiconductor pattern 119d may be positioned so that the upper surface of the light-blocking layer 113 is in contact with one surface of each of the third semiconductor pattern 119i and the fourth semiconductor pattern 119d.

The third semiconductor pattern 119i may include a first portion disposed between the first spacer pattern 120a and the light-blocking layer 113, and a second portion disposed between the second spacer pattern 120b and the light-blocking layer 113. An area where the first portion of the third semiconductor pattern 119i is disposed may be the first area a (see FIG. 3) in the width direction of the channel area. An area where the second portion of the third semiconductor pattern 119i is disposed may be the second area b (see FIG. 3) in the width direction of the channel area. That is, the first and second areas a and b may be arranged in the width direction of the channel area.

The third semiconductor pattern 119i may include amorphous silicon that is not doped with impurities.

The fourth semiconductor pattern 119d may be disposed in the third area c between the first area a and the second area b. The fourth semiconductor pattern 119d may include amorphous silicon doped with a second conductive impurity. For example, the second conductive impurity may include an n-type impurity. The n-type impurity may include phosphorus (P), arsenic (As), or antimony (Sb). In another example, the fourth semiconductor pattern 119d may include a semiconductor material that may be doped with the second conductive impurity.

In the first area a, the first spacer pattern 120a may be disposed on the third semiconductor pattern 119i. In the second area b, the second spacer pattern 120b may be disposed on the third semiconductor pattern 119i. Each of the first spacer pattern 120a and the second spacer pattern 120b may include silicon oxide (SiOₓ) or silicon nitride (SiNₓ). However, embodiments of the present disclosure are not limited thereto.

The space G may be defined between the first spacer pattern 120a and the second spacer pattern 120b. The buffer layer 123 may be disposed on the substrate 110. The buffer layer 123 may be disposed on the first spacer pattern 120a, the second spacer pattern 120b, and the fourth semiconductor pattern 119d. The buffer layer 123 may cover the inclined surface of each of the first spacer pattern 120a and the second spacer pattern 120b.

The buffer layer 123 may fill the space G between the first spacer pattern 120a and the second spacer pattern 120b. In addition, the buffer layer 123 may be disposed on the upper surface of each of the first spacer pattern 120a and the second spacer pattern 120b.

The vertical level of the upper surface of each of the first spacer pattern 120a and the second spacer pattern 120b is higher than the vertical level of the upper surface of the fourth semiconductor pattern 119d. Thus, the buffer layer 123 may have different thicknesses in the first area a, the second area b, and the third area c.

The active layer 125 may be disposed on the buffer layer 123. The fourth semiconductor pattern 119d disposed in the third area c may include amorphous silicon doped with the second conductive impurity.

The fourth semiconductor pattern 119d may be positioned to face the active layer 125. Accordingly, the fourth semiconductor pattern 119d may further absorb the ultraviolet ray in an amount corresponding to the band gap of the fourth semiconductor pattern 119d. In an embodiment of the present disclosure, the light incident on the active layer 125 may be absorbed by the light-blocking layer 113 and the fourth semiconductor pattern 119d, thereby preventing the reliability of the active layer 125 including the oxide semiconductor from being deteriorated.

Furthermore, the thin-film transistor according to an embodiment of the present disclosure may have the first capacitance C1 generated in the third area c, and the second capacitance C2 generated in each of the first area a and the second area b. The magnitude of the second capacitance C2 may be larger than the magnitude of the first capacitance C1. The second capacitances C2 respectively generated in the first area a and the second area b may have the same magnitude. In addition, each of the first area a and the second area b may include the driving current Ion of the first current amount, and the third area c may include the driving current Ion of the second current amount greater than the first current amount.

Accordingly, the entire current amount of the driving current Ion of the thin-film transistor may be the third current amount as the sum of the first current amount and the second current amount.

Therefore, the S-factor value may be controlled to have a high value while the driving current Ion is not lowered. Thus, the switching characteristics of the thin-film transistor may be maintained while the thin-film transistor may advantageously achieve the low-gray level expression.

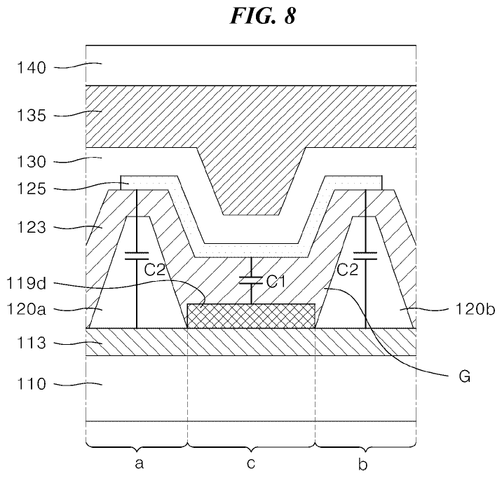

FIG. 8 shows a variant example of a thin-film transistor according to one embodiment of the present disclosure.

In the thin-film transistor according to FIG. 8, the fourth semiconductor pattern 119d may be disposed in the third area c. The fourth semiconductor pattern 119d may include amorphous silicon doped with the second conductive impurity. For example, the second conductive impurity may include an n-type impurity. The n-type impurity may include phosphorus (P), arsenic (As), or antimony (Sb). In another example, the fourth semiconductor pattern 119d may include a semiconductor material that may be doped with the second conductive impurity.

The first spacer pattern 120a and the second spacer pattern 120b may be respectively disposed in the first area a and the second area b disposed on both opposing sides of the third area c, respectively. One surface of each of the first spacer pattern 120a and the second spacer pattern 120b may be in contact with the light-blocking layer 113. Since the fourth semiconductor pattern 119d is disposed on the light-blocking layer 113, bottom surfaces of the semiconductor pattern 119d, the first spacer pattern 120a and the second spacer pattern 120b may be coplanar with each other.

The buffer layer 123 may be disposed in the first area a, the second area b, and the third area c. For example, the buffer layer 123 may be disposed on the first spacer pattern 120a, the second spacer pattern 120b, and the fourth semiconductor pattern 119d. The buffer layer 123 may cover the inclined surface of each of the first spacer pattern 120a and the second spacer pattern 120b.

The buffer layer 123 may have different thicknesses in the first area a, the second area b, and the third area c. For example, the buffer layer 123 may have a relatively larger thickness in the third area c than the thickness thereof in each of the first area a and the second area b.

The active layer 125 may be disposed on the buffer layer 123. The fourth semiconductor pattern 119d disposed in the third area c may include amorphous silicon doped with the second conductive impurity.

The fourth semiconductor pattern 119d may be positioned to face the active layer 125. The fourth semiconductor pattern 119d including the semiconductor material doped with the second conductive impurity may further absorb the ultraviolet rays in an amount corresponding to the band gap of the fourth semiconductor pattern 119d. The light incident on the active layer 125 may be absorbed by the light-blocking layer 113 and the fourth semiconductor pattern 119d. Accordingly, the active layer 125 including the oxide semiconductor may be prevented from being damaged by light or may be prevented from having characteristics deteriorated due to the light.

The thin-film transistor may be configured to have the first capacitance C1 in the third area c, and the second capacitance C2 in each of the first area a and the second area b. The magnitude of the second capacitance C2 may be larger than the magnitude of the first capacitance C1. The second capacitances C2 respectively generated in the first area a and the second area b may have the same magnitude. In addition, each of the first area a and the second area b may include a driving current Ion of a first current amount, and the third area c may include a driving current Ion of a second current amount greater than the first current amount.

Accordingly, the entire current amount of the driving current Ion of the thin-film transistor may be the third current amount as the sum of the first current amount and the second current amount.

Therefore, the S-factor value may be controlled to have a high value while the driving current Ion is not lowered. Thus, the switching characteristics of the thin-film transistor may be maintained while the thin-film transistor may advantageously achieve the low-gray level expression.

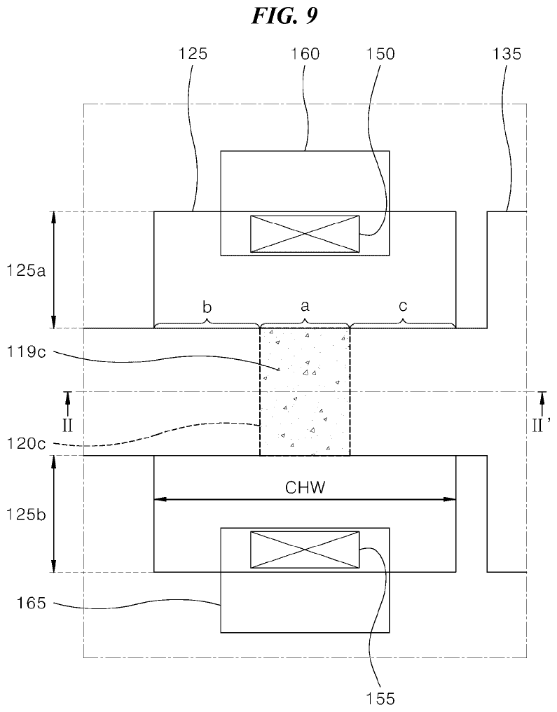

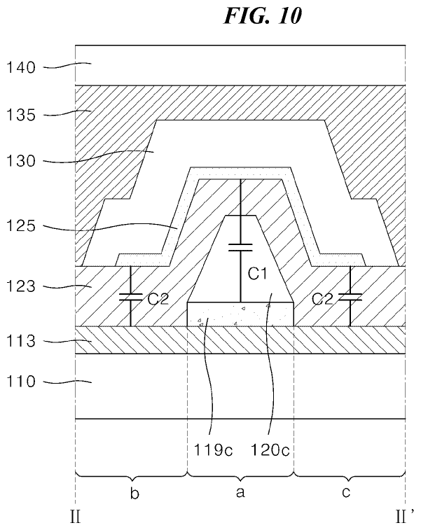

FIG. 9 is a plan view of a thin-film transistor according to another embodiment of the present disclosure. FIG. 10 is a cross-sectional view taken along a line II-II′ of FIG. 9. In FIG. 9 and FIG. 10, the same reference numerals are given to the same components as those of the thin-film transistors as described above with reference to FIG. 3 and FIG. 4, and the descriptions thereof are simplified or omitted.

Referring to FIG. 9 and FIG. 10, the light-blocking layer 113 may be disposed on the substrate 110. The light-blocking layer 113 may be positioned to overlap the active layer 125 in the vertical direction. The light-blocking layer 113 may protect the active layer 125 of the thin-film transistor 100 by blocking light incident thereto from the outside. The light-blocking layer 113 may include an opaque metal material.

A structure may be disposed on the light-blocking layer 113. The structure may include a semiconductor pattern 119c.

The semiconductor pattern 119c may be positioned at a center of an entire area of the active layer 125. However, embodiments of the present disclosure are not limited thereto. An area where the semiconductor pattern 119c is disposed may be referred to as a first area a. One side area around the first area a where the semiconductor pattern 119c is disposed may be referred to as a second area b. Furthermore, the other side area around the first area a where the semiconductor pattern 119c is disposed and opposite to the second area b may be referred to as a third area c.

The semiconductor pattern 119c may include a silicon-based semiconductor material. The semiconductor pattern 119c may include amorphous silicon doped with a first conductive type impurity. For example, the first conductive type impurity may include a p-type impurity. The p-type impurity may include boron (B), indium (In), gallium (Ga), or aluminum (Al). In another example, the semiconductor pattern 119c may include a semiconductor material that may be doped with the first conductive type impurity.

A spacer pattern 120c may be disposed on an upper surface of the semiconductor pattern 119c. Accordingly, the spacer pattern 120c may be disposed in the first area a. The spacer pattern 120c may have a width that becomes smaller as the spacer pattern 220c extends upwardly. Accordingly, a width of a bottom surface of the spacer pattern 120c may be larger than a width of the upper surface thereof. The spacer pattern 120c may include an inclined side surface extending from the upper surface toward the bottom surface thereof.

The spacer pattern 120c may have a thickness larger than a thickness of the semiconductor pattern 119c. For example, the spacer pattern 120c may have a thickness greater than two times of the thickness of the semiconductor pattern 119c. However, embodiments of the present disclosure are not limited thereto. The spacer pattern 120c may be formed as a single layer or a stack of multiple layers including silicon oxide (SiOₓ) or silicon nitride (SiNₓ). However, embodiments of the present disclosure are not limited thereto.

The buffer layer 123 may be disposed on the spacer pattern 120c and the light-blocking layer 113. The buffer layer 123 may cover the inclined side surface of the spacer pattern 120c. The buffer layer 123 may cover both opposing side walls of the semiconductor pattern 119c.

The buffer layer 123 may be disposed on a stack of the semiconductor pattern 119c and the spacer pattern 120c that protrudes from an upper surface of the light-blocking layer 113 and thus may have different thicknesses in different areas. For example, in the first area a where the spacer pattern 120c is disposed, the buffer layer 123 may have a first thickness. In addition, in each of the second area b and the third area c where the upper surface of the light-blocking layer 113 is not covered with the semiconductor pattern 119c, the buffer layer 123 may have a second thickness. In this case, the portion of the buffer layer 123 disposed in each of the second area b and the third area c may have a relatively larger thickness than the thickness of the portion of the buffer layer 123 disposed in the first area a. That is, the second thickness may be larger than the first thickness.

In addition, the buffer layer 123 may be disposed on the stack of the semiconductor pattern 119c and the spacer pattern 120c that protrudes from the upper surface of the light-blocking layer 113 and thus may include the upper surface having different vertical levels in different areas. Thus, the upper surface thereof may have steps. For example, a vertical level of the upper surface of the portion of the buffer layer 123 disposed in the first area a may be higher than a vertical level of the upper surface of the portion of the buffer layer 123 disposed in each of the second area b and the third area c. In this case, the buffer layer 123 may be constructed such that a step may be formed between the first area a and the second area b and a step may be formed between the first area a and the third area c.

The buffer layer 123 may include silicon oxide (SiOₓ) or silicon nitride (SiNₓ). However, embodiments of the present disclosure are not limited thereto.

The active layer 125 may be disposed on the buffer layer 123. The active layer 125 may include an oxide semiconductor material. The active layer 125 may be disposed on the upper surface of the buffer layer 123 in the conformal manner. Accordingly, the active layer 125 may have different vertical levels in different areas thereof. For example, the active layer 125 may be constructed such that a step may be formed between the first area a and the second area b and a step may be formed between the first area a and the third area c. In other words, the vertical levels of the upper surfaces in the different areas of the active layer 125 may be different from each other. Accordingly, the entire upper surface area size of the active layer 125 may be relatively increased, compared to that in a case when the active layer 125 is formed to have a flat upper surface.

The gate electrode 135 may be disposed on top of the active layer 125 while the gate insulating layer 130 is interposed therebetween. The gate electrode 135 may be positioned to overlap the active layer 125 in the vertical direction.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 extending through the interlayer insulating layer 140 and the gate insulating layer 130. The second electrode 165 may be electrically connected to the second area 125b of the active layer 125 via the second contact hole 155 extending through the interlayer insulating layer 140 and the gate insulating layer 130.

The thin-film transistor may comprise the active layer 125, the gate electrode 135, the first electrode 160, and the second electrode 165 formed in this manner.

The first area a includes a sum of thicknesses of the spacer pattern 120c and the buffer layer 123 disposed between the active layer 125 and the semiconductor pattern 119c, so that a first capacitance C1 may be generated in the first area a. Each of the second area b and the third area c respectively disposed on both opposing sides of the first area includes a thickness of the buffer layer 123 disposed between the active layer 125 and the light-blocking layer 113, so that a second capacitance C2 may be generated in each of the second area b and the third area c. The first capacitance C1 may have a larger magnitude than that of the second capacitance C2. The second capacitances C2 respectively generated in the second area b and the third area c may have the same magnitude.

In the first area a where the first capacitance C1 is generated, the threshold voltage increases. In each of the second area b and the third area c where the second capacitance C2 is generated, the threshold voltage may decrease relatively compared to that in the first area a. In the first area a, the spacer pattern 120c and the buffer layer 123 are disposed such that the first area has a relatively larger thickness than that of each of the second area b and the third area c, so that the driving current Ion in the first area a may have a first current amount. In addition, each of the second area b and the third area c is composed of a single layer, that is, the buffer layer 123 such that an insulating material with a relatively smaller thickness than that of the first area a is disposed in each of the second area b and the third area c, so that the driving current Ion in each of the second area b and the third area c may have a second current amount greater than the first current amount.

Accordingly, the driving current Ion of the thin-film transistor may have a third current amount as a sum of the first current amounts and the second current amount based on the current characteristic of the transistors connected to each other in parallel with each other in the channel width CHW direction.

Therefore, while the driving current Ion is not reduced, a high S-factor value may be secured. Thus, while the switching characteristics of the thin-film transistor may be maintained, the thin-film transistor may advantageously perform low-gray level expression.

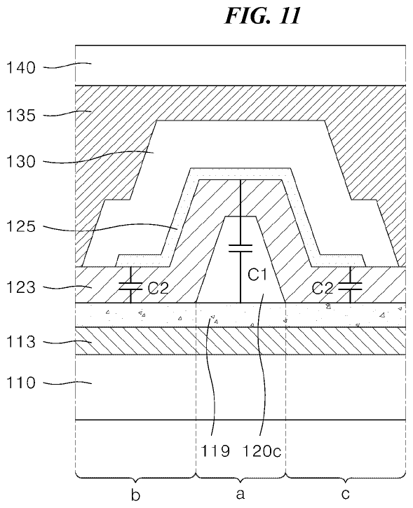

FIG. 11 shows a variant example of a thin-film transistor according to another embodiment of the present disclosure.

Referring to FIG. 11, a thin-film transistor according to another embodiment of the present disclosure may have the semiconductor layer 119 disposed on the light-blocking layer 113.

The semiconductor layer 119 may include a silicon-based semiconductor material. The semiconductor layer 119 may include amorphous silicon doped with a first conductive impurity. For example, the first conductive impurity may include a p-type impurity. The p-type impurity may include boron (B), indium (In), gallium (Ga), or aluminum (Al). In another example, the semiconductor layer 119 may include a semiconductor material that may be doped with a first conductive impurity.

The semiconductor layer 119 may be positioned to extend from the first area a under the spacer pattern 120c to the second area b and to the third area c. The semiconductor layer 119 may be positioned to face the active layer 125 in the second area b and the third area c, that is, to overlap the active layer 125 in the second area b and the third area c. Accordingly, in the second area b and the third area c, the semiconductor layer 119 may further absorb the ultraviolet rays in an amount corresponding to the band gap of the semiconductor layer 119, thereby preventing the characteristics of the active layer 125 from being deteriorated.

The spacer pattern 120c disposed on the semiconductor layer 119 may have a width that becomes smaller as the spacer pattern 120c extends upwardly and may include an inclined side surface.

The buffer layer 123 may be disposed on the spacer pattern 120c and the semiconductor layer 119. The buffer layer 123 may cover the inclined surface and the upper surface of the spacer pattern 120c.

The buffer layer 123 may be disposed on the semiconductor layer 119 and the spacer pattern 120c that protrudes from an upper surface of the semiconductor layer 119 and thus may have different vertical levels in different areas of the upper surface thereof. For example, the vertical level of the upper surface of the buffer layer 123 in the first area a where the spacer pattern 120c is disposed may be higher than the vertical level of the upper surface of the buffer layer 123 in each of the second area b and the third area c where the buffer layer 123 directly contacts the upper surface of the semiconductor layer 119. In this case, the buffer layer 123 may have an inclined surface in a combination of the first area a and the second area b and have an inclined surface in a combination of the first area a and the third area c.

The active layer 125 may be disposed on the buffer layer 123 and may also extend along a profile of the upper surface of the buffer layer 123 in the conformal manner. Thus, the active layer 125 may have different vertical levels in different areas of the upper surface thereof. The vertical level of the upper surface of the active layer 125 in the first area a may be higher than the vertical level of the upper surface of the active layer 125 in each of the second area b and the third area c. Thus, the active layer 125 may have an inclined upper surface in the combination of the first area a and the second area b, and may have an inclined upper surface in the combination of the first area a and the third area c.

The gate electrode 135 may be disposed on the active layer 125 while the gate insulating layer 130 is interposed therebetween.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 extending through the interlayer insulating layer 140 and the gate insulating layer 130. The second electrode 165 may be electrically connected to the second area 125b of the active layer 125 via the second contact hole 155 extending through the interlayer insulating layer 140 and the gate insulating layer 130.

The thin-film transistor may comprise the active layer 125, the gate electrode 135, the first electrode 160, and the second electrode 165 formed in this manner.

The first capacitance C1 may be generated in the first area a. In each of the second area b and the third area c respectively disposed on both opposing sides of the first area a, the second capacitance C2 may be generated. The first capacitance C1 may have a larger magnitude than that of the second capacitance C2. The second capacitances C2 respectively generated in the second area b and the third area c may have the same magnitude.

In this way, the capacitances C1 and C2 of different magnitude may be generated in the different areas in a single thin-film transistor, such that the current amount of the total driving current Ion of the thin-film transistor may be increased. Therefore, while the driving current Ion is not reduced, a high S-factor value may be secured. Thus, while the switching characteristics of the thin-film transistor may be maintained, the thin-film transistor may advantageously perform low-gray level expression.

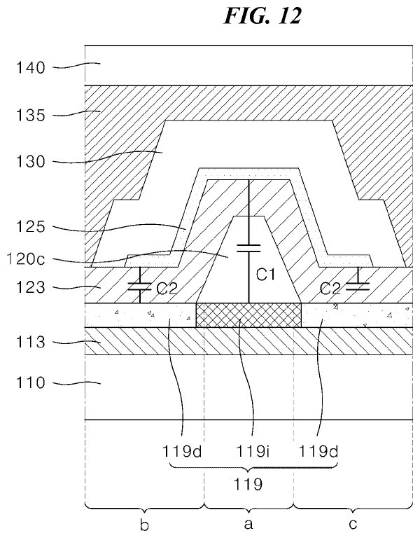

FIG. 12 shows a variant example of a thin-film transistor according to another embodiment of the present disclosure.

Referring to FIG. 12, the semiconductor structure 119 may be disposed on the light-blocking layer 113. The semiconductor structure 119 may include one or more semiconductor patterns. The semiconductor structure 119 may include the third semiconductor pattern 119i and the fourth semiconductor pattern 119d.

The third semiconductor pattern 119i may be disposed in a corresponding manner to or in an overlapping manner with the first area a where the spacer pattern 120c is disposed. The fourth semiconductor pattern 119d may be disposed in each of the second area b and the third area c while the third semiconductor pattern 119i is disposed therebetween.

The third semiconductor pattern 119i may include amorphous silicon that is not doped with impurities.

The fourth semiconductor pattern 119d may include amorphous silicon doped with a second conductive impurity. For example, the second conductive impurity may include an n-type impurity. The n-type impurity may include phosphorus (P), arsenic (As), or antimony Sb. In another example, the fourth semiconductor pattern 119d may include a semiconductor material that may be doped with a second conductive impurity.

The buffer layer 123 may be disposed on the spacer pattern 120c and the fourth semiconductor pattern 119d. The buffer layer 123 may cover the inclined surface and the upper surface of the spacer pattern 120c. A vertical level of the upper surface of the portion of the buffer layer 123 disposed in the first area a may be higher than a vertical level of the upper surface of the portion of the buffer layer 123 disposed in each of the second area b and the third area c. In this case, the buffer layer 123 may have an inclined surface in the combination of the first area a and the second area b and an inclined surface in the combination of the first area a and the third area c.

The active layer 125 may be disposed on the buffer layer 123 and may also extend along a profile of the upper surface of the buffer layer 123 in the conformal manner. Thus, the active layer 125 may have different vertical levels in different areas of the upper surface thereof. The vertical level of the upper surface of the active layer 125 in the first area a may be higher than the vertical level of the upper surface of the active layer 125 In each of the second area b and the third area c. Thus, the active layer 125 may have an inclined upper surface in the combination of the first area a and the second area b, and may have an inclined upper surface in the combination of the first area a and the third area c.

The gate electrode 135 may be disposed on the active layer 125 while the gate insulating layer 130 is interposed therebetween.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 extending through the interlayer insulating layer 140 and the gate insulating layer 130. The second electrode 165 may be electrically connected to the second area 125b of the active layer 125 via the second contact hole 155 extending through the interlayer insulating layer 140 and the gate insulating layer 130.

The fourth semiconductor pattern 119d disposed on each of the second area b and the third area c of the substrate 110 may be positioned to face the active layer 125 or to overlap therewith. Thus, the fourth semiconductor pattern 119d may further absorb the ultraviolet ray in an amount corresponding to the band gap of the fourth semiconductor pattern 119d. In an embodiment of the present disclosure, the light incident on the active layer 125 may be absorbed by the light-blocking layer 113 and the fourth semiconductor pattern 119d, thereby preventing the reliability of the active layer 125 including the oxide semiconductor from being deteriorated.

The thin-film transistor may comprise the active layer 125, the gate electrode 135, the first electrode 160, and the second electrode 165 formed in this manner.

The first capacitance C1 may be generated in the first area a. In each of the second area b and the third area c respectively disposed on both opposing sides of the first area a, the second capacitance C2 may be generated. The first capacitance C1 may have a larger magnitude than that of the second capacitance C2. The second capacitances C2 respectively generated in the second area b and the third area c may have the same magnitude.

In this way, the capacitances C1 and C2 of different magnitude may be generated in the different areas in a single thin-film transistor, such that the current amount of the total driving current Ion of the thin-film transistor may be increased. Therefore, while the driving current Ion is not reduced, a high S-factor value may be secured. Thus, while the switching characteristics of the thin-film transistor may be maintained, the thin-film transistor may advantageously perform low-gray level expression.

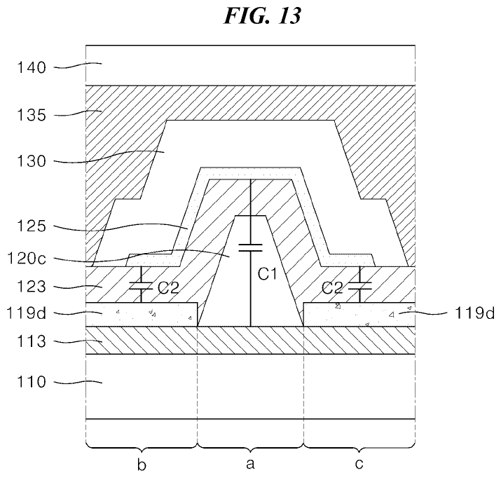

FIG. 13 shows a variant example of a thin-film transistor according to another embodiment of the present disclosure.

Referring to FIG. 13, a lower surface of the spacer pattern 120c disposed on the first area a of the substrate 110 may be positioned to be in contact with the light-blocking layer 113. The fourth semiconductor pattern 119d may be disposed on each of the second area b and the third area c respectively disposed on both opposing sides of the spacer pattern 120c which is disposed therebetween.

The fourth semiconductor pattern 119d may include amorphous silicon doped with a second conductive impurity. For example, the second conductive impurity may include an n-type impurity. The n-type impurity may include phosphorus (P), arsenic (As), or antimony (Sb). In another example, the fourth semiconductor pattern 119d may include a semiconductor material that may be doped with a second conductive impurity.

The fourth semiconductor pattern 119d may be disposed on the light-blocking layer 113. Thus, bottom surfaces of the semiconductor patterns 119d and the spacer pattern 120c may be coplanar with each other.

The buffer layer 123 may be disposed on the first area a, the second area b, and the third area c. For example, the buffer layer 123 may be disposed on the spacer pattern 120c and the fourth semiconductor patterns 119d. The buffer layer 123 may cover the inclined surface and the upper surface of the spacer pattern 120c.

The active layer 125 may be disposed on the buffer layer 123 and may also extend along a profile of the upper surface of the buffer layer 123 in the conformal manner. Thus, the active layer 125 may have different vertical levels in different areas of the upper surface thereof. The vertical level of the upper surface of the active layer 125 in the first area a may be higher than the vertical level of the upper surface of the active layer 125 in each of the second area b and the third area c. Thus, the active layer 125 may have an inclined upper surface in the combination of the first area a and the second area b, and may have an inclined upper surface in the combination of the first area a and the third area c.

The gate electrode 135 may be disposed on the active layer 125 while the gate insulating layer 130 is interposed therebetween.

The interlayer insulating layer 140 may be disposed on the gate electrode 135. The first electrode 160 and the second electrode 165 may be disposed on the interlayer insulating layer 140. The first electrode 160 may be electrically connected to the first area 125a of the active layer 125 via the first contact hole 150 extending through the interlayer insulating layer 140 and the gate insulating layer 130. The second electrode 165 may be electrically connected to the second area 125b of the active layer 125 via the second contact hole 155 extending through the interlayer insulating layer 140 and the gate insulating layer 130.

The fourth semiconductor pattern 119d may be positioned to face the active layer 125 in each of the second area b and the third area c of the substrate 110. That is, the fourth semiconductor pattern 119d may be positioned to overlap the active layer 125 in each of the second area b and the third area c of the substrate 110. Thus, each of the fourth semiconductor patterns 119d may further absorb the ultraviolet ray in an amount corresponding to the band gap of each of the fourth semiconductor patterns 119d. In an embodiment of the present disclosure, the light incident on the active layer 125 may be absorbed by the light-blocking layer 113 and the fourth semiconductor patterns 119d, thereby preventing the reliability of the active layer 125 including the oxide semiconductor from being deteriorated.

The thin-film transistor may comprise the active layer 125, the gate electrode 135, the first electrode 160, and the second electrode 165 formed in this manner.

The first capacitance C1 may be generated in the first area a. In each of the second area b and the third area c respectively disposed on both opposing sides of the first area a, the second capacitance C2 may be generated. The first capacitance C1 may have a larger magnitude than that of the second capacitance C2. The second capacitances C2 respectively generated in the second area b and the third area c may have the same magnitude.

In this way, the capacitances C1 and C2 of different magnitude may be generated in the different areas in a single thin-film transistor, such that the current amount of the total driving current Ion of the thin-film transistor may be increased. Therefore, while the driving current Ion is not reduced, a high S-factor value may be secured. Thus, while the switching characteristics of the thin-film transistor may be maintained, the thin-film transistor may advantageously perform low-gray level expression.

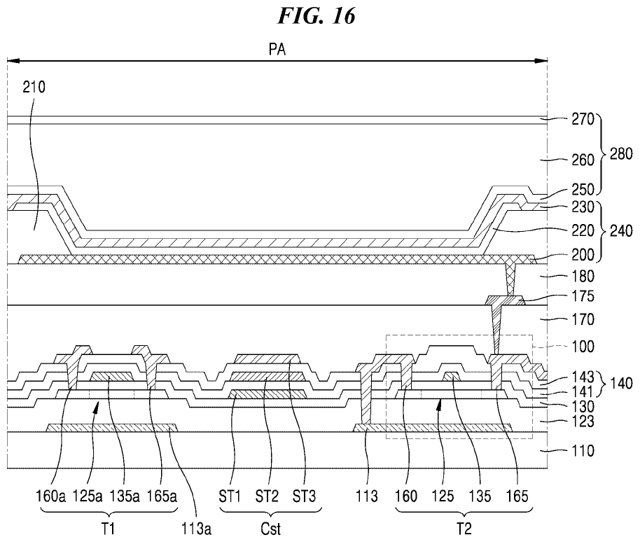

FIG. 16 is a cross-sectional view showing one of pixel areas of a display apparatus including a thin-film transistor according to some embodiments of the present disclosure in an enlarged manner. An example in which the display apparatus is embodied as an organic light-emitting diode display apparatus is described below. However, embodiments of the present disclosure are not limited thereto.

Referring to FIG. 16, a first thin-film transistor T1, a second thin-film transistor T2, and a storage capacitor Cst may be disposed on a substrate 110 and in a pixel area PA. For example, the second thin-film transistor T2 may include at least one thin-film transistor 100 among the thin-film transistors as described in FIGS. 3 to 13 of the present disclosure.

The first thin-film transistor T1 may be, for example, a switching transistor. The second thin-film transistor T2 may be, for example, a driving thin-film transistor.

The light-blocking layer 113 and a first light-blocking layer 113a may be disposed on the substrate 110. The first light-blocking layer 113a may be disposed under the first thin-film transistor T1, and the light-blocking layer 113 may be positioned at a different position from a position of the first light-blocking layer 113a.

The light-blocking layer 113 may be disposed under the second thin-film transistor T2.

The buffer layer 123 may be disposed on the light-blocking layer 113 and the first light-blocking layer 113a. In one example, one of the structures as described in FIG. 3 to FIG. 13 according to some embodiments of the present disclosure may be disposed between the light-blocking layer 113 and the buffer layer 123.

The active layer 125 may be disposed on the buffer layer 123. A first active layer 125a may be positioned at a different location from a position of the active layer 125. The gate insulating layer 130 may be disposed on the active layer 125 and the first active layer 125a. the gate electrode 135 may be disposed on the gate insulating layer 130. The gate electrode 135 may be positioned to overlap the active layer 125 in a vertical direction. The first gate electrode 135a may be positioned at a different location from that of the gate electrode 135.

The interlayer insulating layer 140 may be disposed on the gate electrode 135 and the first gate electrode 135a. For example, the interlayer insulating layer 140 may include a multilayer including a first interlayer insulating layer 141 and a second interlayer insulating layer 143. However, embodiments of the present disclosure are not limited thereto.

The first electrode 160 and the second electrode 165 may be disposed on the interlayer insulating layer 140. The first electrode 160 may extend through the interlayer insulating layer 140 and the gate insulating layer 130 so as to be electrically connected to one side of the active layer 125. Furthermore, the second electrode 165 may extend through the interlayer insulating layer 140 and the gate insulating layer 130 so as to be electrically connected to the other side of the active layer 125. At locations different from the positions of the first electrode 160 and the second electrode 165, a first electrode 160a of the first thin-film transistor T1 and a second electrode 165a of the first thin-film transistor T1 may be positioned. Each of the first electrode 160a of the first thin-film transistor T1 and the second electrode 165a of the first thin-film transistor T1 may be electrically connected to the first active layer 125a.

The second thin-film transistor T2 may include the active layer 125, the gate electrode 135, the first electrode 160, and the second electrode 165. The first thin-film transistor T1 may include the first active layer 125a, the first gate electrode 135a, the first electrode 160a, and the second electrode 165a.

The storage capacitor Cst of each pixel area PA may include a stack structure of capacitor electrodes ST1, ST2, and ST3. The storage capacitor Cst may include a first capacitor electrode ST1, a second capacitor electrode ST2, and a third capacitor electrode ST3. The storage capacitor Cst may be formed within a corresponding pixel area PA in a process of forming the first thin-film transistor T1 and the second thin-film transistor T2. For example, the first capacitor electrode ST1 and the gate electrode 135 may be disposed on the same layer. The second capacitor electrode ST2 may be disposed on the first interlayer insulating layer 141. The third capacitor electrode ST3 and the second electrode 165 may be disposed on the same layer. Accordingly, an area size occupied with the storage capacitor Cst within each pixel area PA may be minimized.

A first planarization layer 170 may be disposed on the interlayer insulating layer 140, the first electrode 160, and the second electrode 165. The first planarization layer 170 may planarize a step caused by the underlying circuit elements such as the first thin-film transistor T1, the second thin-film transistor T2, and the storage capacitor Cst. The first planarization layer 170 may include an organic insulating material such as acryl. However, embodiments of the present disclosure are not limited thereto.

A connection electrode 175 may be disposed on the first planarization layer 170. The connection electrode 175 may be electrically connected to the second electrode 165 of the second thin-film transistor T2 via a contact hole extending through the first planarization layer 170. However, the present disclosure is not limited thereto. In another example, the connecting electrode 175 may be electrically connected to the first electrode 160 of the second thin-film transistor T2. A second planarization layer 180 may be disposed on the first planarization layer 170.

A light-emitting element 240 may be disposed on the second flattening layer 180. The light-emitting element 240 may include an anode electrode 200, a light-emitting layer 220, and a cathode electrode 230. In this regard, the anode electrode 200 may be referred to as a pixel electrode, and the cathode electrode 230 may be referred to as a counter electrode. However, the present disclosure is not limited to these terms. The light-emitting element 240 of the present disclosure may be embodied as an organic light-emitting diode element. However, embodiments of the present disclosure are not limited thereto, and various types of light-emitting elements may be used.

The anode electrode 200 may be disposed on the second flattening layer 180. One surface of the anode electrode 200 may be in contact with an upper surface of the connection electrode 175. Accordingly, the anode electrode 200 may be electrically connected to the thin-film transistor 100 via the connection electrode 175 and the first electrode 160.

The anode electrode 200 may include a metal oxide such as indium tin oxide (ITO) or indium zinc oxide (IZO). However, embodiments of the present disclosure are not limited thereto. Alternatively, the anode electrode 200 may include a single-layer or a multi-layer structure including a reflective metal film made of silver (Ag), aluminum (Al), gold (Au), nickel (Ni), chromium (Cr), and compounds thereof.

A bank 210 may be disposed on the second planarization layer 180. The bank 210 may distinguish neighboring pixels from each other. For this purpose, the bank 210 may be formed to cover an edge of the anode electrode 200. Furthermore, the bank 210 may prevent different colors of different light beams output from adjacent pixels from being mixed with each other. The bank 210 may include an organic insulating film made of, for example, polyimide or epoxy. However, embodiments of the present disclosure are not limited thereto.

The light-emitting layer 220 may be disposed on the anode electrode 200. In one example, the light-emitting layer 220 may include an organic material that emits each of light beams of different colors in different pixels. For example, the light-emitting layer 220 may emit light of one color among red, green, blue, and white. In another example, the light-emitting layer 220 may be made of an organic material that emits white light, and one color among red, green, or blue may be generated using a color filter.

The cathode electrode 230 may be disposed on the light-emitting layer 220. The cathode electrode 230 may be formed to cover the light-emitting layer 220. The cathode electrode 230 may be commonly formed across a plurality of pixels. The cathode electrode 230 may include a metal oxide such as indium tin oxide (ITO) or indium zinc oxide (IZO). However, embodiments of the present disclosure are not limited thereto. Alternatively, the cathode electrode 230 may include a single-layer or a multi-layer structure including a reflective metal film made of silver (Ag), aluminum (Al), gold (Au), nickel (Ni), chromium (Cr), and compounds thereof.

An encapsulation portion 280 may be disposed on the cathode electrode 230. The encapsulation part 280 may include a first encapsulation layer 250, a second encapsulation layer 260, and a third encapsulation layer 270.

The first encapsulation layer 250 may be disposed on the cathode electrode 230. The first encapsulation layer 250 may include an inorganic insulating material. For example, the first encapsulation layer 250 may include at least one inorganic insulating material among silicon nitride (SiNₓ), silicon oxide (SiOₓ), and silicon oxynitride (SiON).

The second encapsulation layer 260 may cover the first encapsulation layer 250 and have a sufficient thickness so as to have a flat upper surface. The second encapsulation layer 260 may prevent foreign substances from invading into the light-emitting element 240. The second encapsulation layer 260 may include an organic insulating material. For example, the second encapsulation layer 260 may include at least one material selected from epoxy, polyimide, polyethylene, and acrylate.

The third encapsulation layer 270 may be disposed on the second encapsulation layer 260. The third encapsulation layer 270 may include an inorganic insulating material. For example, the third encapsulation layer 255 may include at least one inorganic insulating material among silicon nitride (SiNₓ), silicon oxide (SiOₓ), and silicon oxynitride (SiON).

A display apparatus according to various embodiments of the present disclosure may be described as follows.

A first aspect of the present disclosure provides a thin-film transistor comprising: a substrate; an active layer disposed on the substrate; a gate electrode disposed on the active layer; a buffer layer disposed between the active layer and the substrate; and a semiconductor structure disposed under at least a portion of the buffer layer and overlapping at least a portion of the active layer.

In accordance with some embodiments of the thin-film transistor of the first aspect, the active layer includes a channel area overlapping the gate electrode in a vertical direction, wherein the channel area includes: a first area as one side area of the active layer overlapping the gate electrode; a second area as the other side area of the active layer overlapping the gate electrode; and a third area defined between the first area and the second area, wherein the semiconductor structure is positioned so as to overlap at least one of the first area, the second area, and the third area.

In accordance with some embodiments of the thin-film transistor of the first aspect, the active layer includes an oxide semiconductor material.

In accordance with some embodiments of the thin-film transistor of the first aspect, the first area, the second area, and the third area are arranged along a first direction of the channel area, wherein the first direction is a width direction of the channel area.

In accordance with some embodiments of the thin-film transistor of the first aspect, the semiconductor structure includes: a first semiconductor pattern positioned so as to overlap the first area; and a second semiconductor pattern positioned so as to overlap the second area.

In accordance with some embodiments of the thin-film transistor of the first aspect, the thin-film transistor further comprises: a first spacer pattern disposed on the first semiconductor pattern; and a second spacer pattern disposed on the second semiconductor pattern.

In accordance with some embodiments of the thin-film transistor of the first aspect, each of the first spacer pattern and the second spacer pattern has a width gradually smaller as each of the first spacer pattern and the second spacer pattern extends upwardly, wherein each of the first spacer pattern and the second spacer pattern has an inclined side surface extending in an inclined manner between lower and upper surfaces thereof.

In accordance with some embodiments of the thin-film transistor of the first aspect, the buffer layer is disposed on the upper surface and the inclined side surface of each of the first spacer pattern and the second spacer pattern, and fills a space overlapping the third area.

In accordance with some embodiments of the thin-film transistor of the first aspect, the buffer layer has: a first portion overlapping the third area and filling the space of the third area, wherein the first portion has a first thickness; a second portion overlapping the first area and having a second thickness; and a third portion overlapping the second area and having the second thickness, wherein the first thickness is greater than the second thickness.

In accordance with some embodiments of the thin-film transistor of the first aspect, wherein an upper surface of the active layer is divided into at least two areas having different vertical levels.

In accordance with some embodiments of the thin-film transistor of the first aspect, each of the first semiconductor pattern and the second semiconductor pattern includes amorphous silicon doped with a first conductive type impurity.

In accordance with some embodiments of the thin-film transistor of the first aspect, the first conductive impurity is a p-type impurity including boron (B), indium (In), gallium (Ga), or aluminum (Al).

In accordance with some embodiments of the thin-film transistor of the first aspect, the semiconductor structure is positioned so as to overlap all of the first area, the second area, and the third area.

In accordance with some embodiments of the thin-film transistor of the first aspect, the semiconductor structure includes amorphous silicon doped with a first conductive impurity, wherein the first conductive impurity includes a p-type impurity.

In accordance with some embodiments of the thin-film transistor of the first aspect, the semiconductor structure includes: a third semiconductor pattern positioned so as to overlap each of the first area and the second area; and a fourth semiconductor pattern with the material different from the third semiconductor pattern and positioned so as to overlap the third area.

In accordance with some embodiments of the thin-film transistor of the first aspect, the third semiconductor pattern includes amorphous silicon not doped with an impurity, wherein the fourth semiconductor pattern includes amorphous silicon doped with a second conductive impurity, wherein the second conductive impurity includes an n-type impurity.

In accordance with some embodiments of the thin-film transistor of the first aspect, the semiconductor structure is positioned so as to only overlap the third area.

In accordance with some embodiments of the thin-film transistor of the first aspect, the thin-film transistor further comprises a spacer pattern disposed on the semiconductor structure.

In accordance with some embodiments of the thin-film transistor of the first aspect, the semiconductor structure includes amorphous silicon doped with a first conductive impurity, wherein the first conductive impurity includes a p-type impurity.

In accordance with some embodiments of the thin-film transistor of the first aspect, wherein the semiconductor structure comprises: a fourth semiconductor pattern disposed to only overlap with the third area, wherein the fourth semiconductor pattern includes amorphous silicon doped with a second conductive impurity, wherein the second conductive impurity includes an n-type impurity.

In accordance with some embodiments of the thin-film transistor of the first aspect, wherein the thin-film transistor further comprises: a first spacer pattern disposed on the semiconductor structure in the first area; and a second spacer pattern disposed on the semiconductor structure in the second area, wherein the semiconductor structure includes amorphous silicon doped with a first conductive impurity, wherein the first conductive impurity includes a p-type impurity.

In accordance with some embodiments of the thin-film transistor of the first aspect, wherein the thin-film transistor further comprises: a spacer pattern disposed on the semiconductor structure in the third area.

In accordance with some embodiments of the thin-film transistor of the first aspect, wherein the thin-film transistor further comprises: a spacer pattern disposed between the first semiconductor pattern and the second semiconductor pattern and disposed in the third area.

A second aspect of the present disclosure provides a display apparatus comprising: a light-emitting element; and a thin-film transistor connected to the light-emitting element, wherein the thin-film transistor includes the thin-film transistor of the first aspect.

In accordance with some embodiments of the display apparatus of the second aspect, the light-emitting element includes: a first electrode connected to the thin-film transistor; a light-emitting layer disposed on the first electrode; and a second electrode disposed on the light-emitting layer.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin-film transistor comprising:
a substrate;
an active layer on the substrate;
a gate electrode on the active layer;
a buffer layer between the active layer and the substrate; and
a semiconductor structure disposed under at least a portion of the buffer layer and overlapping at least a portion of the active layer.

2. The thin-film transistor of claim 1, wherein the active layer includes a channel area overlapping the gate electrode in a vertical direction,
wherein the channel area includes:
a first area as one side area of the active layer overlapping the gate electrode;
a second area as the other side area of the active layer overlapping the gate electrode; and
a third area defined between the first area and the second area,
wherein the semiconductor structure is positioned to overlap at least one of the first area, the second area, and the third area.

3. The thin-film transistor of claim 1, wherein the active layer includes an oxide semiconductor material.

4. The thin-film transistor of claim 2, wherein the first area, the second area, and the third area are arranged along a first direction of the channel area, and
wherein the first direction is a width direction of the channel area.

5. The thin-film transistor of claim 2, wherein the semiconductor structure includes:
a first semiconductor pattern positioned to overlap the first area; and
a second semiconductor pattern positioned to overlap the second area.

6. The thin-film transistor of claim 5, wherein the thin-film transistor further comprises:
a first spacer pattern on the first semiconductor pattern; and
a second spacer pattern on the second semiconductor pattern.

7. The thin-film transistor of claim 6, wherein each of the first spacer pattern and the second spacer pattern has a width gradually smaller as each of the first spacer pattern and the second spacer pattern extends upwardly, and
wherein each of the first spacer pattern and the second spacer pattern has an inclined side surface extending in an inclined manner between lower and upper surfaces thereof.

8. The thin-film transistor of claim 7, wherein the buffer layer is on the upper surface and the inclined side surface of each of the first spacer pattern and the second spacer pattern, and is present in a space overlapping the third area.

9. The thin-film transistor of claim 8, wherein the buffer layer includes:
a first portion overlapping the third area and filling the space of the third area, the first portion having a first thickness;
a second portion overlapping the first area, the second portion having a second thickness; and
a third portion overlapping the second area, the third portion having the second thickness,
wherein the first thickness is greater than the second thickness.

10. The thin-film transistor of claim 9, wherein an upper surface of the active layer is divided into at least two areas having different vertical levels.

11. The thin-film transistor of claim 5, wherein each of the first semiconductor pattern and the second semiconductor pattern includes amorphous silicon doped with a first conductive type impurity.

12. The thin-film transistor of claim 11, wherein the first conductive impurity is a p-type impurity including boron (B), indium (In), gallium (Ga), or aluminum (Al).

13. The thin-film transistor of claim 2, wherein the semiconductor structure is positioned to overlap the first area, the second area, and the third area.

14. The thin-film transistor of claim 13, wherein the semiconductor structure includes amorphous silicon doped with a first conductive impurity, and
wherein the first conductive impurity includes a p-type impurity.

15. The thin-film transistor of claim 13, wherein the semiconductor structure includes:
a third semiconductor pattern positioned to overlap each of the first area and the second area; and
a fourth semiconductor pattern with the material different from the third semiconductor pattern and positioned to overlap the third area.

16. The thin-film transistor of claim 15, wherein the third semiconductor pattern includes amorphous silicon not doped with an impurity,
wherein the fourth semiconductor pattern includes amorphous silicon doped with a second conductive impurity, and
wherein the second conductive impurity includes an n-type impurity.

17. The thin-film transistor of claim 2, wherein the semiconductor structure is positioned to only overlap the third area.

18. The thin-film transistor of claim 17, wherein the thin-film transistor further comprises a spacer pattern on the semiconductor structure.

19. The thin-film transistor of claim 17, wherein the semiconductor structure includes amorphous silicon doped with a first conductive impurity, and
wherein the first conductive impurity includes a p-type impurity.

20. The thin-film transistor of claim 17, wherein the semiconductor structure includes:
a fourth semiconductor pattern disposed to only overlap with the third area,
wherein the fourth semiconductor pattern includes amorphous silicon doped with a second conductive impurity, and
wherein the second conductive impurity includes an n-type impurity.

21. The thin-film transistor of claim 13, wherein the thin-film transistor further comprises:
a first spacer pattern on the semiconductor structure in the first area; and
a second spacer pattern on the semiconductor structure in the second area,
wherein the semiconductor structure includes amorphous silicon doped with a first conductive impurity, and
wherein the first conductive impurity includes a p-type impurity.

22. The thin-film transistor of claim 14, wherein the thin-film transistor further comprises:
a spacer pattern on the semiconductor structure in the third area.

23. The thin-film transistor of claim 5, wherein the thin-film transistor further comprises:
a spacer pattern disposed between the first semiconductor pattern and the second semiconductor pattern and disposed in the third area.

24. A display apparatus comprising:
a light-emitting element; and
a thin-film transistor electrically connected to the light-emitting element,
wherein the thin-film transistor includes:
a substrate;
an active layer on the substrate;
a gate electrode on the active layer;
a buffer layer between the active layer and the substrate; and
a semiconductor structure disposed under at least a portion of the buffer layer and overlapping at least a portion of the active layer from a plan view.

25. The display apparatus of claim 24, wherein the light-emitting element includes:
a first electrode electrically connected to the thin-film transistor;
a light-emitting layer on the first electrode; and
a second electrode on the light-emitting layer.
